(19) United States
(12) Patent Application Publication
(10) Pub. No.: US 2026/0280540 A1
(43) Pub. Date: Sep. 17, 2026

(54) CIRCUIT AND METHOD FOR IMPROVING SENSING ACCURACY

(71) Applicant: Realtek Semiconductor Corp., HsinChu (TW)

(72) Inventors: Chung-Yao Chang, HsinChu (TW); Chuan-Hu Lin, HsinChu (TW)

(73) Assignee: Realtek Semiconductor Corp., HsinChu (TW)

(21) Appl. No.: 19/534,695

(22) Filed: Feb. 9, 2026

(30) Foreign Application Priority Data
Mar. 13, 2025 (TW) 114109371

(51) Int. Cl. H03K 5/135; H03F 1/02; H04B 1/525

(52) U.S. Cl. CPC H03K 5/135; H03F 1/0277; H04B 1/525

(57) ABSTRACT

A processing circuit includes a delay circuit for outputting a delayed signal according to a first path delay coefficient; a control circuit for determining a clock phase sampling time according to a second path delay coefficient and outputting a controlled signal according to the clock phase sampling time; a transforming circuit for transforming the controlled signal to a transformed signal; a mixing circuit for mixing the delayed signal and the transformed signal, to generate a mixed signal; a removing circuit for removing a direct current (DC) component of the mixed signal, to generate a removed signal; a computing circuit for computing the first path delay coefficient, the second path delay coefficient and a signal power according to the removed signal; an amplifying circuit for amplifying an amplitude of the removed signal, to generate an amplified signal; and a combining circuit for combining a plurality of chirps in the amplified signal.

### BACKGROUND OF THE INVENTION

### 1. Field of the Invention

The present disclosure relates to a circuit and a method used in a wireless communication system, and more particularly, to a circuit and a method for improving sensing accuracy.

### 2. Description of the Prior Art

A sensing device is an electronic device that senses presence, motion and/or range of an object. During the sensing process, a transmitter of the sensing device transmits a signal, which is reflected by an object and then received by a receiver of the sensing device. The signal received by the sensing device comprises not only the target signal but also any noise and interference (e.g., transmitter-to-receiver (T2R) leakage). This noise and interference cause a loss of an effective number of bits (ENOB) in the internal circuit of the sensing device, increase the noise level, and exacerbate an IQ phase mismatch. As sensing accuracy of the sensing device will be reduced, how to improve the sensing accuracy is an important problem to be solved.

### SUMMARY OF THE INVENTION

The present disclosure provides a circuit and a method to solve the abovementioned problem.

A processing circuit for improving a sensing accuracy comprises: a delay circuit, for outputting a delayed signal according to a first path delay coefficient; a control circuit, for determining a clock phase sampling time according to a second path delay coefficient and outputting a controlled signal according to the clock phase sampling time; a transforming circuit, coupled to the control circuit, for transforming the controlled signal to a transformed signal; a mixing circuit, coupled to the delay circuit and the transforming circuit, for mixing the delayed signal and the transformed signal, to generate a mixed signal; a removing circuit, coupled to the mixing circuit, for removing a direct current (DC) component of the mixed signal, to generate a removed signal; a computing circuit, coupled to the delay circuit, the control circuit and the removing circuit, for computing the first path delay coefficient, the second path delay coefficient and a signal power according to the removed signal; an amplifying circuit, coupled to the removing circuit and the computing circuit, for amplifying an amplitude of the removed signal according to the signal power, to generate an amplified signal; and a combining circuit, coupled to the amplifying circuit, for combining a plurality of chirps in the amplified signal, to generate a combined signal.

A method for improving a sensing accuracy comprises: outputting a delayed signal according to a first path delay coefficient; determining a clock phase sampling time according to a second path delay coefficient and outputting a controlled signal according to the clock phase sampling time; transforming the controlled signal to a transformed signal; mixing the delayed signal and the transformed signal, to generate a mixed signal; removing a direct current (DC) component of the mixed signal, to generate a removed signal; computing the first path delay coefficient, the second path delay coefficient and a signal power according to the removed signal; amplifying an amplitude of the removed signal according to the signal power, to generate an amplified signal; and combining a plurality of chirps in the amplified signal, to generate a combined signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a sensing device according to an example of the present disclosure.

FIG. 2 is a schematic diagram of a processing circuit according to an example of the present disclosure.

FIG. 3 is a schematic diagram of a control circuit according to an example of the present disclosure.

FIG. 4 is a schematic diagram of a clock phase according to an example of the present disclosure.

FIG. 5 is a schematic diagram of a delay circuit according to an example of the present disclosure.

FIG. 6 is a schematic diagram of a computing result according to an example of the present disclosure.

FIG. 7 is a schematic diagram of a sensing result according to an example of the present disclosure.

FIG. 8 is a flowchart of a process according to an example of the present disclosure.

FIG. 9 is a flowchart of a process according to an example of the present disclosure.

### DETAILED DESCRIPTION

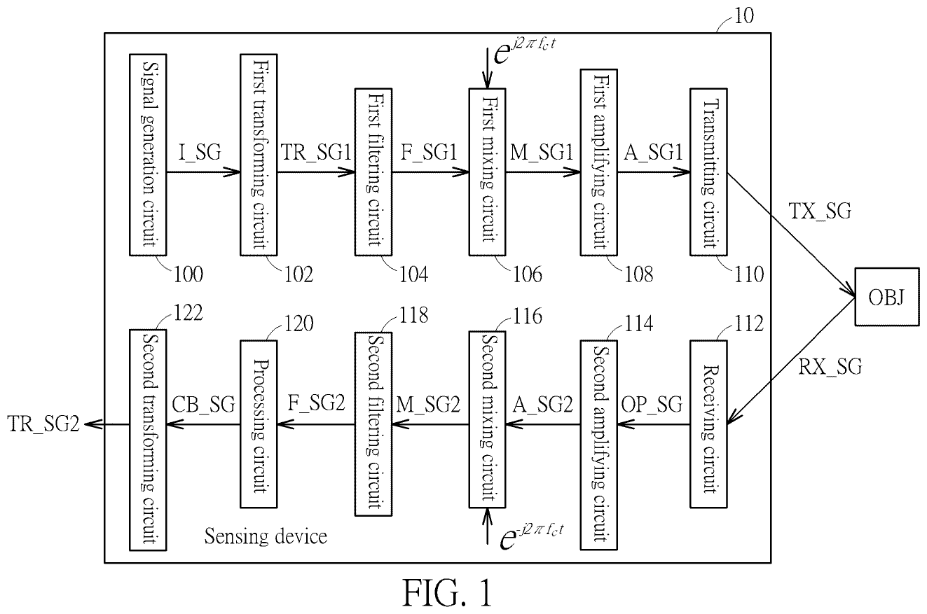

FIG. 1 is a schematic diagram of a sensing device 10 according to an example of the present disclosure. The sensing device 10 may be applied in a wireless communication system such as a wireless local area network (WLAN), a Long Term Evolution (LTE) system, an LTE-advanced (LTE-A) system, a 5th generation (5G) system, etc. The sensing device 10 may support an Institute of Electrical and Electronics Engineers (IEEE) standard (e.g., 802.11AX, 802.11be or a subsequent version). The IEEE 802.11 standard may support an Orthogonal Frequency Division Multiple Access (OFDMA) and/or a Multi-User Multiple-Input Multiple-Output (MU-MIMO). In one example, the sensing device 10 may be a Frequency Modulated Continuous Wave (FMCW) device.

As shown in FIG. 1, the sensing device 10 comprises a signal generation circuit 100, a first transforming circuit 102, a first filtering circuit 104, a first mixing circuit 106, a first amplifying circuit 108, a transmitting circuit 110, a receiving circuit 112, a second amplifying circuit 114, a second mixing circuit 116, a second filtering circuit 118, a processing circuit 120 and a second transforming circuit 122. The signal generation circuit 100, the first transforming circuit 102, the first filtering circuit 104, the first mixing circuit 106, the first amplifying circuit 108 and the transmitting circuit 110 can be seen as a transmitter. The receiving circuit 112, the second amplifying circuit 114, the second mixing circuit 116, the second filtering circuit 118, the processing circuit 120 and the second transforming circuit 122 can be seen as a receiver.

In the transmitter, the signal generation circuit 100 is configured to generate an initial signal I_SG. The initial signal I_SG comprises a chirp signal, wherein the chirp signal comprises one or more chirps. The first transforming circuit 102 is coupled to the signal generation circuit 100, and is configured to transform the initial signal I_SG to a first transformed signal TR_SG1. The first filtering circuit 104 is coupled to the first transforming circuit 102, and is configured to filter the first transformed signal TR_SG1, to generate a first filtered signal F_SG1. The first mixing circuit 106 is coupled to the first filtering circuit 104, and is configured to mix the first filtered signal F_SG1 according to a periodic signal (e.g., e^{j2πf}^{_{c}}^{t}, wherein f_{c} is a carrier frequency), to generate a first mixed signal M_SG1. In one example, the first mixing circuit 106 is further coupled to an oscillation circuit (not shown in FIG. 1), and obtains the periodic signal from the oscillation circuit. The first amplifying circuit 108 is coupled to the first mixing circuit 106, and is configured to amplify an amplitude of the first mixed signal M_SG1 (e.g., multiply the amplitude of the first mixed signal M_SG1 by an amplification coefficient of the first amplifying circuit 108), to generate a first amplified signal A_SG1. The transmitting circuit 110 is coupled to the first amplifying circuit 108, and is configured to input the first amplified signal A_SG1 and transmit (or output) a transmitted signal TX_SG. In one example, the transmitted signal TX_SG comprises the first amplified signal A_SG1.

In the receiver, the receiving circuit 112 is configured to receive a received signal RX_SG corresponding to the transmitted signal TX_SG and output an output signal OP_SG. In one example, the received signal RX_SG is the transmitted signal TX_SG reflected by the object OBJ and then received by the receiving circuit 112. In one example, the output signal OP_SG comprises the received signal RX_SG. The second amplifying circuit 114 is coupled to the receiving circuit 112, and is configured to amplify an amplitude of the output signal OP_SG (e.g., multiply the amplitude of the output signal OP_SG by an amplification coefficient of the second amplifying circuit 114), to generate a second amplified signal A_SG2. The second mixing circuit 116 is coupled to the second amplifying circuit 114, and is configured to mix the second amplified signal A_SG2 according to a periodic signal (e.g., e^{-j2πf}^{_{c}}^{t}), to generate a second mixed signal M_SG2. In one example, the second mixing circuit 116 is further coupled to the oscillation circuit (not shown in FIG. 1), and obtains the periodic signal from the oscillation circuit. The second filtering circuit 118 is coupled to the second mixing circuit 116, and is configured to filter the second mixed signal M_SG2, to generate a second filtered signal F_SG2. The processing circuit 120 is coupled to the signal generation circuit 100 and the second filtering circuit 118, and is configured to process the second filtered signal F_SG2 according to the initial signal I_SG, to generate a combined signal CB_SG. The second transforming circuit 122 is coupled to the processing circuit 120, and is configured to transform the combined signal CB_SG to the second transformed signal TR_SG2, to obtain a sensing result.

In one example, at least one of the output signal OP_SG, the second amplified signal A_SG2, the second mixed signal M_SG2 and the second filtered signal F_SG2 comprises leakage signal(s) (not shown in FIG. 1). The leakage signal(s) is noise that leaks from the transmitter to the receiver within the sensing device 10. The leakage signal is eliminated through the operation of the processing circuit 120. That is, the combined signal CB_SG and the second transformed signal TR_SG2 do not comprise the leakage signal(s).

In one example, the first transforming circuit 102 comprises a digital-to-analog converter (DAC). In one example, the first filtering circuit 104 comprises a low pass filter (LPF). In one example, the first amplifying circuit 108 comprises a power amplifier (PA). In one example, the second amplifying circuit 114 comprises a low-noise amplifier (LAN). In one example, the second filtering circuit 118 comprises an LPF. In one example, the second transforming circuit 122 comprises a Fast Fourier Transform (FFT) circuit. In one example, the FFT circuit performs at least one of a Range-FFT, a Doppler-FFT and an Angle-FFT.

In one example, the initial signal I_SG and the combined signal CB_SG are time-domain digital signals. In one example, the first transformed signal TR_SG1, the first filtered signal F_SG1, the first mixed signal M_SG1, the first amplified signal A_SG1, the transmitted signal TX_SG, the received signal RX_SG, the output signal OP_SG, the second amplified signal A_SG2, the second mixed signal M_SG2 and the second filtered signal F_SG2 are time-domain analog signals. In one example, the second transformed signal TR_SG2 is a frequency-domain digital signal.

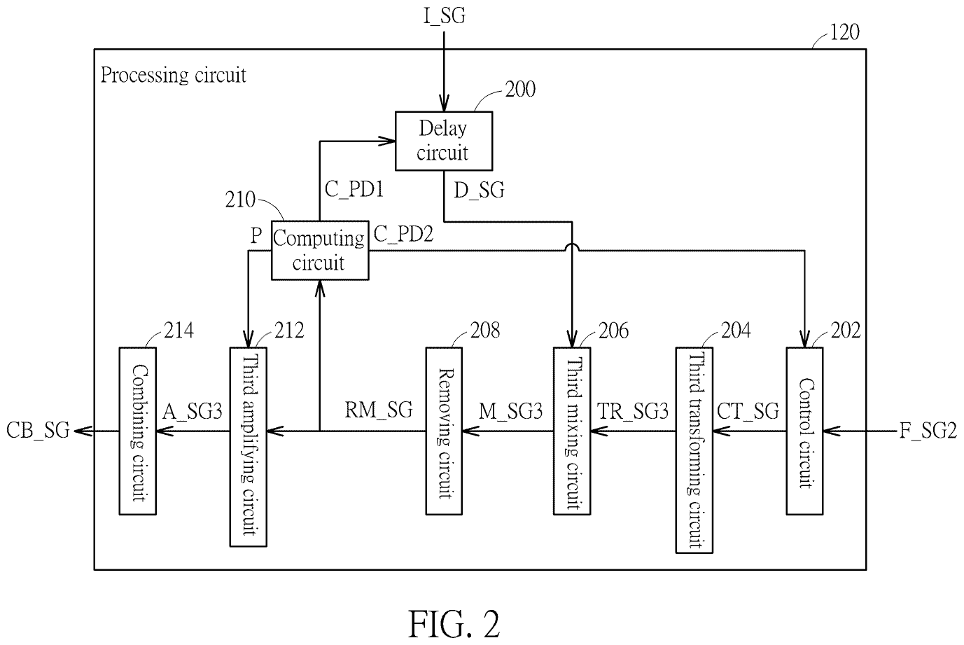

FIG. 2 is a schematic diagram of a processing circuit 120 according to an example of the present disclosure. The processing circuit 120 comprises a delay circuit 200, a control circuit 202, a third transforming circuit 204, a third mixing circuit 206, a removing circuit 208, a computing circuit 210, a third amplifying circuit 212 and a combining circuit 214. In detail, the delay circuit 200 is coupled to the signal generation circuit 100 in FIG. 1, and is configured to output a delayed signal D_SG according to a first path delay coefficient C_PD1. The control circuit 202 is coupled to the second filtering circuit 118 in FIG. 1, and is configured to determine a clock phase sampling time according to a second path delay coefficient C_PD2 and output a controlled signal CT_SG corresponding to the second filtered signal F_SG2 according to the clock phase sampling time. The third transforming circuit 204 is coupled to the control circuit 202, and is configured to transform the controlled signal CT_SG to a third transformed signal TR_SG3. The third mixing circuit 206 is coupled to the delay circuit 200 and the third transforming circuit 204, and is configured to mix the delayed signal D_SG and the third transformed signal TR_SG3, to generate a third mixed signal M_SG3. The removing circuit 208 is coupled to the third mixing circuit 206, and is configured to remove a direct current (DC) component of the third mixed signal M_SG3, to generate a removed signal RM_SG. The computing circuit 210 is coupled to the delay circuit 200, the control circuit 202 and the removing circuit 208, and is configured to compute the first path delay coefficient C_PD1, the second path delay coefficient C_PD2 and a signal power P according to the removed signal RM_SG. The third amplifying circuit 212 is coupled to the removing circuit 208 and the computing circuit 210, and is configured to amplify an amplitude of the removed signal RM_SG according to the signal power P, to generate a third amplified signal A_SG3. The combining circuit 214 is coupled to the third amplifying circuit 212 and the second transforming circuit 122 in FIG. 1, and is configured to combine a plurality of chirps in the third amplified signal A_SG3, to generate a combined signal CB_SG.

In one example, the step of the delay circuit 200 outputting the delayed signal D_SG according to the first path delay coefficient C_PD1 comprises: delaying the initial signal I_SG, to generate a plurality of candidate delayed signals; and selecting a candidate delayed signal from the plurality of candidate delayed signals as the delayed signal D_SG according to the first path delay coefficient C_PD1. In one example, the step of the control circuit 202 determining the clock phase sampling time according to the second path delay coefficient C_PD2 comprises: dividing a sampling time of the third transforming circuit 204 into a plurality of candidate clock phase sampling times; and selecting a candidate clock phase sampling time from the plurality of candidate clock phase sampling times as the clock phase sampling time according to the second path delay coefficient C_PD2.

In one example, the step of the computing circuit 210 computing the first path delay coefficient C_PD1, the second path delay coefficient C_PD2 and the signal power P according to the removed signal RM_SG comprises: (A) setting a value of a phase counter as a first initial value, and setting the signal power P as a second initial value; (B) computing the first path delay coefficient C_PD1 and the second path delay coefficient C_PD2 according to the value of the phase counter, and triggering an output of the initial signal I_SG corresponding to the delayed signal D_SG (i.e., triggering the signal generation circuit 100 to generate (or output) the initial signal I_SG); (C) computing a power of the removed signal RM_SG after a chirp time; (D) increasing the value of the phase counter by 1, resetting that the signal power P is equal to the power of the removed signal RM_SG and performing the step (B) according to the increased value of the phase counter and the reset signal power P, in response to the power of the removed signal RM_SG being smaller than a sum of the signal power P and a detection margin (e.g., 3 dB); and (E) decreasing the value of the phase counter by 1 and computing the first path delay coefficient C_PD1 and the second path delay coefficient C_PD2 according to the decreased value of the phase counter in response to the power of the removed signal RM_SG not being smaller than the sum of the signal power P and the detection margin. In one example, the computing circuit 210 computes an estimated path delay (i.e., an estimated leakage path delay from the transmitter to the receiver) according to at least one of the first path delay coefficient C_PD1, the second path delay coefficient C_PD2 and the decreased value of the phase counter.

In one example, a path of the estimated path delay comprises a path from an input of the first transforming circuit 102 to an output of the transmitting circuit 110, a signal transmission path between the transmitting circuit 110 transmitting the transmitted signal TX_SG and the receiving circuit 112 receiving the received signal RX_SG, and a path from an input of the receiving circuit 112 to an output of the third transforming circuit 204. In one example, the first path delay coefficient C_PD1 is related to an integer part of the estimated path delay. In one example, the second path delay coefficient C_PD2 is related to a fractional part of the estimated path delay.

In one example, the step of the third amplifying circuit 212 amplifying the amplitude of the removed signal RM_SG according to the signal power P to generate the third amplified signal A_SG3 comprises: computing a gain of the removed signal RM_SG according to the signal power P; and multiplying the gain by the amplitude of the removed signal RM_SG. In one example, the gain computed by the third amplifying circuit 212 is used for improving the efficiency and accuracy (e.g., the full scale) of the transformation operation(s) (e.g., the fixed-point operation of the FFT) performed by the second transforming circuit 122.

In one example, the delay circuit 200 comprises a delay line memory. In one example, the control circuit 202 comprises a clock generator. In one example, the third transforming circuit 204 comprises an analog-to-digital converter (ADC). In one example, the delayed signal D_SG, the third transformed signal TR_SG3, the third mixed signal M_SG3, the removed signal RM_SG and the third amplified signal A_SG3 are time-domain digital signals.

In one example, a combining gain is obtained by combining a plurality of chirps in the third amplified signal A_SG3 through the combining circuit 214, in response to a neglect of a received phase change of a chirp in the third amplified signal A_SG3 (i.e., a velocity of an object such as the object OBJ in FIG. 1 is smaller than a threshold, and thus the Doppler effect has a negligible impact on the object). The combining gain G_{cb} can be expressed as the following equation (Eq. 1):

$${G}_{cb} = 10 \cdot {log}_{10} ( {N}_{cb} ) \qquad ( Eq . 1 )$$

wherein N_{cb} is a number of the plurality of chirps. In one example, the combining gain is used for improving a signal-to-noise ratio (SNR) of the third amplified signal A_SG3. That is, an SNR of the combined signal CB_SG is higher than the SNR of the third amplified signal A_SG3.

In one example, a transforming gain is obtained by transforming the combined signal CB_SG to the second transformed signal TR_SG2 through the second transforming circuit 122. The transforming gain G_{T} can be expressed as the following equation (Eq. 2):

$${G}_{T} = 10 \cdot {log}_{10} ( \frac{{f}_{s 3}}{{R}_{IF}} ) \qquad ( Eq . 2 )$$

wherein fₛ₃ is a sampling rate of the third transforming circuit 204 (fₛ₃=2B, wherein B is a sweeping bandwidth), and R_{IF} is an intermediate frequency (IF) resolution

$$( {R}_{IF} = \frac{1}{{T}_{c}} ,$$

wherein T_{c} is a chirp time). In one example, the transforming gain is used for increasing a processing gain of the second transforming circuit 122.

The following example is used for illustrating how the sensing device 10 senses the object. First, a baseband transmitted signal w_{B}(n) (e.g., the initial signal I_SG) generated by the signal generation circuit 100 can be expressed as the following equation (Eq. 3):

$${w}_{B} ( n ) = {e}^{j π \frac{B}{{T}_{c}} {( n {T}_{S 1} )}^{2}} , n = 0 , 1 , 2 , … , {N}_{c} - 1 \qquad ( Eq . 3 )$$

wherein Tₛ₁ is a sampling time of the first transforming circuit 102

$$( {T}_{s 1} = \frac{1}{{f}_{s 1}} ,$$

wherein fₛ₁ is a sampling frequency of the first transforming circuit 102), and N_{c} is a number of sampling points of the first transforming circuit 102. The first transforming circuit 102 and the first filtering circuit 104 process the baseband transmitted signal w_{B}(n), to generate a signal w_{B}(t) (e.g., the first filtered signal F_SG1). Then, the first mixing circuit 106 and the first amplifying circuit 108 process the signal w_{B}(t), to generate a radio frequency (RF) transmitted signal x_{T}(t) (e.g., the first amplified signal A_SG1 and/or the transmitted signal TX_SG). The RF transmitted signal x_{T}(t) can be expressed as the following equation (Eq. 4):

$${x}_{T} ( t ) = {A}_{T} \cdot {w}_{B} ( t ) \cdot {e}^{j 2 π {f}_{c} t} \qquad ( Eq . 4 )$$

wherein f_{c} is a carrier frequency, and A_{T} is an amplification coefficient of the first amplifying circuit 108.

After the transmitting circuit 110 transmits the RF transmitted signal x_{T}(t) and the RF transmitted signal x_{T}(t) is reflected by the object, the receiving circuit 112 receives a received signal y_{R}(t) (e.g., the received signal RX_SG). The received signal y_{R}(t) can be expressed as the following equation (Eq. 5):

$${y}_{R} ( t ) = 1 {0}^{\frac{- L ( R , {f}_{c} , σ )}{20}} \cdot {x}_{T} ( t - τ ) \qquad ( Eq . 5 )$$

wherein L(R, f_{c}, σ) is a path loss related to a range R, the carrier frequency f_{c} and a radar cross-section σ, and τ is a round trip delay. The range R is a range between the sensing device 10 and the object. Then, a baseband received signal y_{B}(t) (e.g., the second filtered signal F_SG2) is obtained through the second amplifying circuit 114, the second mixing circuit 116 and the second filtering circuit 118. The baseband received signal y_{B}(t) can be expressed as the following equation (Eq. 6):

$${y}_{B} ( t ) = A \cdot {y}_{R} ( t ) \cdot {e}^{- j 2 π {f}_{c} t} \qquad ( Eq . 6 )$$

wherein A is an amplification coefficient of the second amplifying circuit 114.

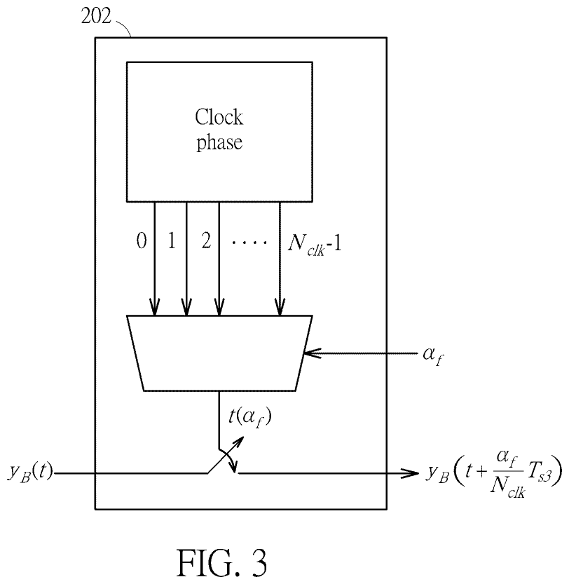

The control circuit 202 in the processing circuit 120 controls an output of the baseband received signal y_{B}(t), which is shown in FIG. 3. In FIG. 3, a sampling time Tₛ₃ of the third transforming circuit 204 is divided into N_{clk} equal parts, a clock phase interval is

$$\frac{{T}_{s 3}}{{N}_{clk}} ,$$

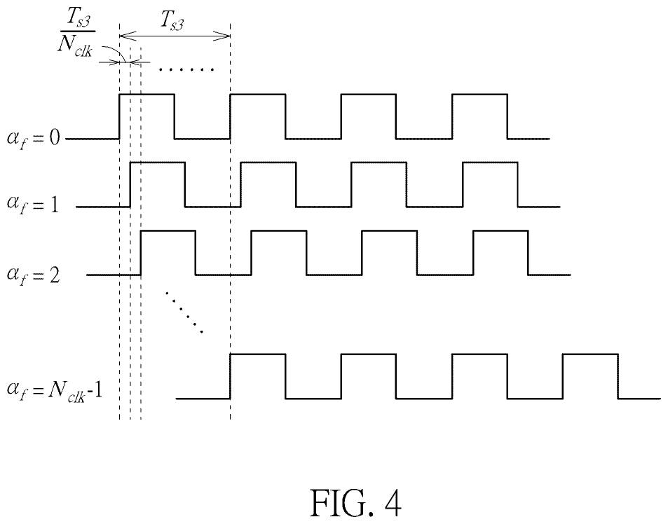

and a path delay coefficient σ_{f} (e.g., the second path delay coefficient C_PD2) is used for controlling an output of the baseband received signal y_{B}(t). Clock phases related to the path delay coefficient α_{f} can be known by referring to FIG. 4. A clock sampling time can be expressed as the following equation (Eq. 7):

$$t ( {α}_{f} ) = t + \frac{{a}_{f}}{{N}_{clk}} {T}_{s 3} , {α}_{f} = 0 , 1 , 2 , … , {N}_{clk} - 1 \qquad ( Eq . 7 )$$

Accordingly, an output signal of the control circuit 202 is

$${y}_{B} ( t + \frac{{α}_{f}}{{N}_{clk}} {T}_{s 3} ) .$$

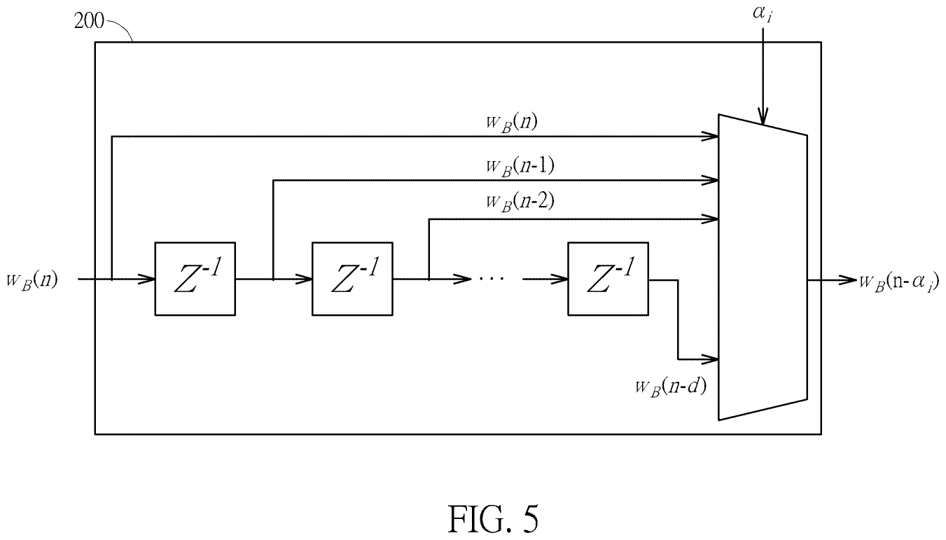

In addition, the delay circuit 200 in the processing circuit 120 delays the baseband transmitted signal w_{B}(n), which is shown in FIG. 5. In FIG. 5, w_{B}(n), w_{B}(n−1), w_{B}(n−2), . . . , w_{B}(n−d) are candidate delayed signals, d is a number of buffers Z⁻¹, and a path delay coefficient αᵢ (e.g., the first path delay coefficient C_PD1) is used for controlling a delayed output of the baseband transmitted signal w_{B}(n). A sampling frequency of the buffer is fₛ₁. Accordingly, an output signal (e.g., the delayed signal D_SG) of the delay circuit 200 is w_{B}(n−αᵢ). In addition, a sampling frequency fₛ₁ of the first transforming circuit 102 and a sampling frequency fₛ₃ of the third transforming circuit 204 are set to the same frequency, i.e., fₛ₁=fₛ₃.

The third transforming circuit 204 in the processing circuit 120 transforms the output signal of the control circuit 202, and the third mixing circuit 206 in the processing circuit 120 mixes the output signals of the delay circuit 200 and the third transforming circuit 204, to generate an IF signal y(n) (e.g., the third mixed signal M_SG3). The IF signal y(n) can be expressed as the following equation (Eq. 8):

$$y ( n ) = {w}_{B} ( n - {α}_{i} ) \cdot {y}_{B}^{′} ( n {T}_{s 3} + \frac{{α}_{f}}{{N}_{clk}} {T}_{s 3} ) \qquad ( Eq . 8 )$$

wherein (⋅)′ is a conjugate operator.

The removing circuit 208 in the processing circuit 120 removes a DC component of the IF signal y(n) as follows:

$${y}_{z} ( n ) = y ( n ) - \frac{1}{{N}_{c}} {\sum }_{n = 0}^{{N}_{c} - 1} y ( n ) \qquad ( Eq . 9 )$$

wherein y_{z}(n) is the IF signal y(n) after removing the DC component (e.g., the removed signal RM_SG), and N_{c} is a number of sampling points in a chirp time T_{c}.

The computing circuit 210 in the processing circuit 120 computes the path delay coefficient di, the path delay coefficient α_{f} and a signal power P_{Z,svr} (e.g., the signal power P) according to a computation process. The computation process comprises the following steps:
Step A: Set a value τ_{c} of a phase counter as a first initial value (e.g., 0), and set the signal power P_{Z,svr} as a second initial value (e.g., ∞).
Step B: Compute the path delay coefficient di and the path delay coefficient of according to the equations (Eq. 10) and (Eq. 11), and trigger the signal generation circuit 100 to output the baseband transmitted signal w_{B}(n).

$${α}_{i} = ⌊ \frac{{τ}_{c}}{{N}_{clk}} ⌋ \qquad ( Eq . 10 )$$

$${α}_{f} = {τ}_{c} - {α}_{i} \cdot {N}_{clk} \qquad ( Eq . 11 )$$

Step C: Compute a power P_{Z} of the signal y_{z}(n). The power P_{Z} can be expressed as the following equation (Eq. 12):

$${P}_{z} = \frac{1}{{N}_{c}} {\sum }_{n = 0}^{{N}_{c} - 1} {\vert {y}_{z} ( n ) \vert}^{2} \qquad ( Eq . 12 )$$

Step D: If P_{Z}< (P_{Z,svr}+P_{marg}), set τ_{c}=τ_{c}+1 and P_{Z,svr}=P_{Z} and perform Step B according to the reset τ_{c} and the reset P_{Z,svr}. P_{marg} is the detection margin (e.g., 3 dB).
Step E: If P_{Z}> (P_{Z,svr}+P_{marg}), set τ_{c}=τ_{c}−1 and compute the path delay coefficient αᵢ, the path delay coefficient of and a path delay \hat{τ}ₜ₂ᵣ according to the reset τ_{c}. The path delay coefficient αᵢ and the path delay coefficient of are obtained according to the equations (Eq. 10) and (Eq. 11). The path delay \hat{τ}ₜ₂ᵣ is obtained according to the equation(s) (Eq. 13) and/or (Eq. 14). The path delay \hat{τ}ₜ₂ᵣ can be expressed as follows:

$${\hat{τ}}_{t 2 r} = {τ}_{c} \cdot \frac{{T}_{s 3}}{{N}_{clk}} \qquad ( Eq . 13 )$$

$${\hat{τ}}_{t 2 r} = {α}_{i} \cdot {T}_{s 3} + {α}_{f} \cdot \frac{{T}_{s 3}}{{N}_{clk}} \qquad ( Eq . 14 )$$

After computing the path delay coefficient αᵢ, the path delay coefficient α_{f} and the path delay \hat{τ}ₜ₂ᵣ, the computing circuit 210 outputs the path delay coefficient αᵢ to the delay circuit 200, outputs the path delay coefficient α_{f} to the control circuit 202, and outputs the path delay \hat{τ}ₜ₂ᵣ to the third amplifying circuit 212 in the processing circuit 120.

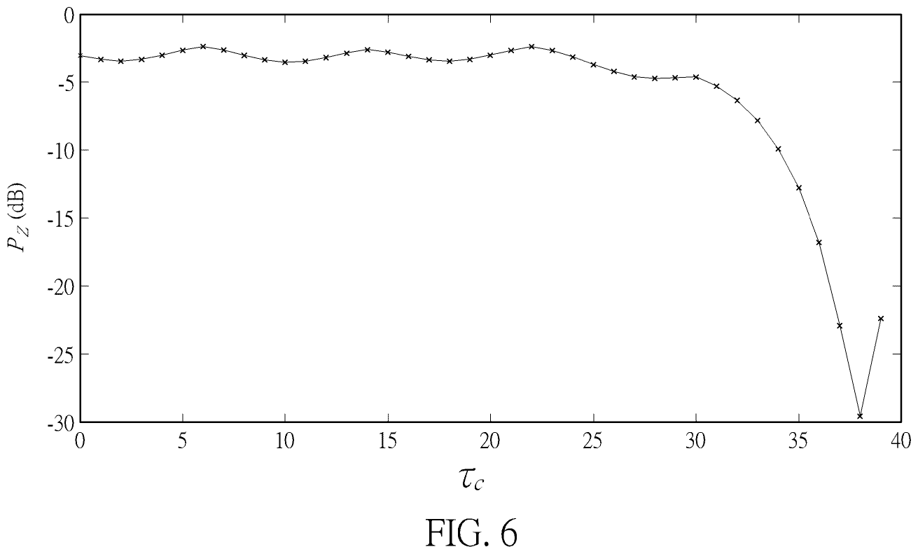

It should be noted that, the IF frequency approaches 0 and the IF signal y(n) approximates the DC component, when the estimated path delay \hat{τ}ₜ₂ᵣ approximates the actual path delay \hat{τ}ₜ₂ᵣ (i.e., \hat{τ}ₜ₂ᵣ≈τₜₑᵣ). That is, in the case where the IF frequency approaches 0, the power of the signal y_{z}(n) has a minimum value and the leakage signal from the transmitter to the receiver is removed. FIG. 6 is a schematic diagram of a computing result according to an example of the present disclosure. FIG. 6 is obtained according to the above computing process (Steps A-E). In FIG. 6, a horizontal axis represents the value τ_{c} of the phase counter, and a vertical axis represents the signal power P_{Z} (dB). The computing result in FIG. 6 shows that the signal power P_{Z} has a minimum when to =38. That is, the estimated path delay \hat{τ}ₜ₂ᵣ is closest to the actual path delay τₜₑᵣ when τ_{c}=38.

Then, the third amplifying circuit 212 computes a gain G and an amplified signal y_{G}(n) (e.g., the third amplified signal A_SG3) according to the signal power P_{Z,svr} output by the computing circuit 210, as shown in the equations (Eq. 15) and (Eq. 16):

$$G = {10}^{\frac{- {P}_{z , svr}}{20}} \qquad ( Eq . 15 )$$

$${y}_{G} ( n ) = G \cdot {y}_{z} ( n ) \qquad ( Eq . 16 )$$

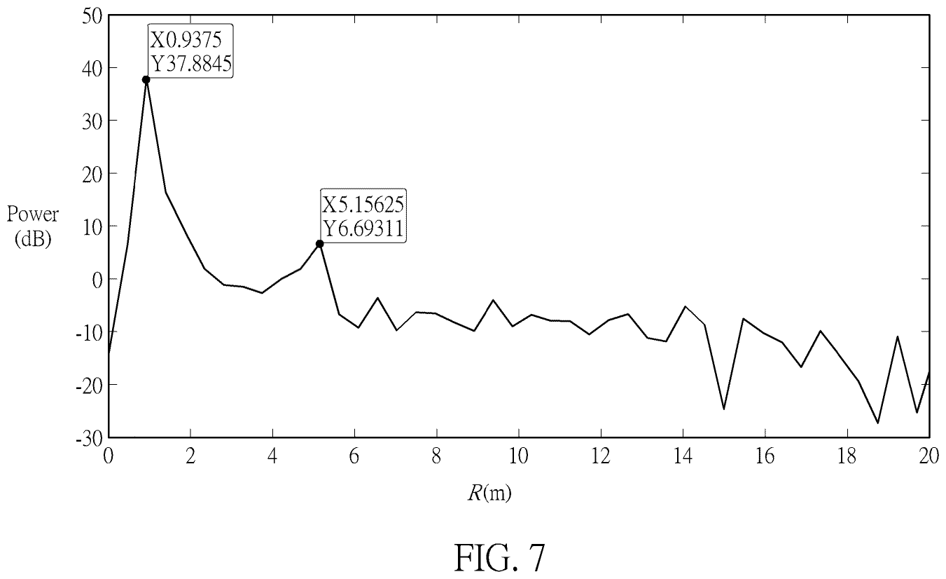

The combining circuit 214 in the processing circuit 120 combines N_{cb} chirps in the amplified signal y_{G}(n), as shown in the equation (Eq. 17):

$$\overline{{y}_{G}} ( n ) = \frac{1}{{N}_{c b}} {\sum }_{k = 0}^{{N}_{cb} - 1} {y}_{G} ( k , n ) , n = 0 , 1 , 2 , … , {N}_{c} - 1 \qquad ( Eq . 17 )$$

wherein y̅_̅{̅G̅}̅(n) is an output signal (e.g., the combined signal CB_SG) of the combining circuit 214. The second transforming circuit 122 in the processing circuit 120 performs the FFT (e.g., the Range-FFT, the Doppler-FFT and/or the Angle-FFT) for the output signal y̅_̅{̅G̅}̅(n) to obtain a sensing result, which is shown in FIG. 7. FIG. 7 shows a sensing result generated by the second transforming circuit 122 performing the Range-FFT. In FIG. 7, a horizontal axis represents a range R (in meters (m)) between the sensing device 10 and the object OBJ, and a vertical axis represents a power (in dB) of the output signal y̅_̅{̅G̅}̅(n) of the combining circuit 214. The sensing result in FIG. 7 shows two peaks, which means that the sensing device 10 senses two objects. The ranges between the two objects and the sensing device 10 are 1 m and 5 m, respectively.

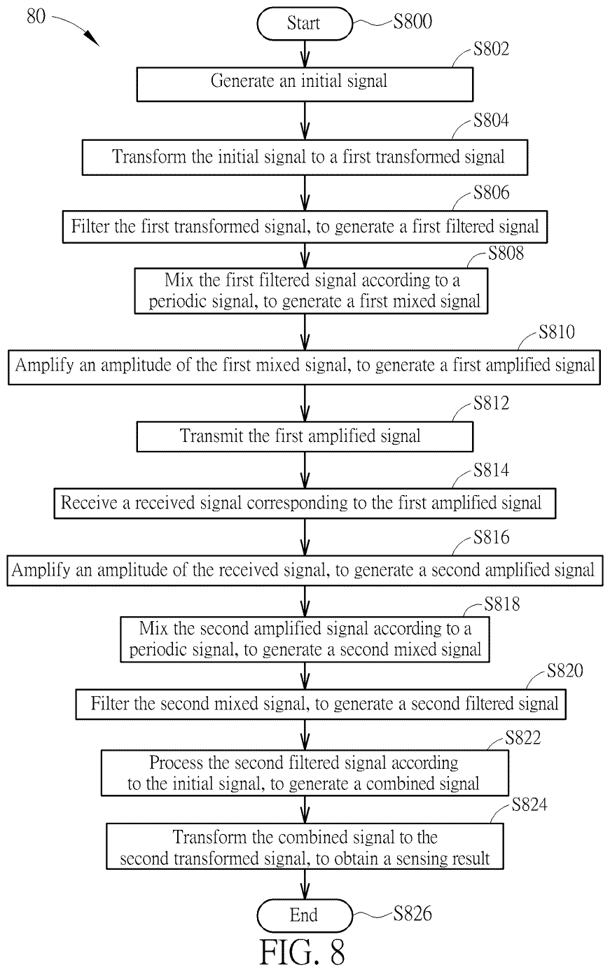

Operations of the sensing device 10 in the above examples can be summarized into a process 80 shown in FIG. 8, which includes the following steps:
Step S800: Start.
Step S802: Generate an initial signal.
Step S804: Transform the initial signal to a first transformed signal.
Step S806: Filter the first transformed signal, to generate a first filtered signal.
Step S808: Mix the first filtered signal according to a periodic signal, to generate a first mixed signal.
Step S810: Amplify an amplitude of the first mixed signal, to generate a first amplified signal.
Step S812: Transmit the first amplified signal.
Step S814: Receive a received signal corresponding to the first amplified signal.
Step S816: Amplify an amplitude of the received signal, to generate a second amplified signal.
Step S818: Mix the second amplified signal according to a periodic signal, to generate a second mixed signal.
Step S820: Filter the second mixed signal, to generate a second filtered signal.
Step S822: Process the second filtered signal according to the initial signal, to generate a combined signal.
Step S824: Transform the combined signal to the second transformed signal, to obtain a sensing result.
Step S826: End.

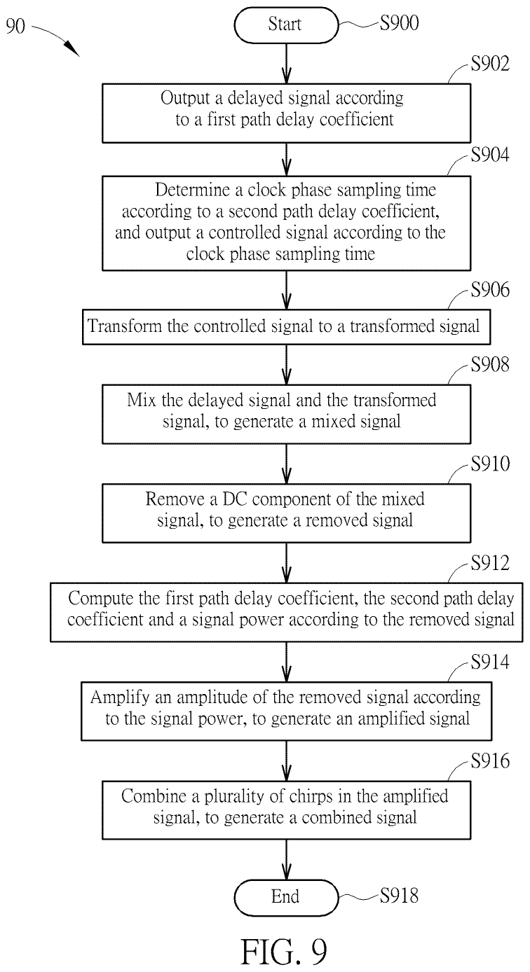

Operations of the processing circuit 120 in the above examples can be summarized into a process 90 shown in FIG. 9, which includes the following steps:
Step S900: Start.
Step S902: Output a delayed signal according to a first path delay coefficient.
Step S904: Determine a clock phase sampling time according to a second path delay coefficient, and output a controlled signal according to the clock phase sampling time.
Step S906: Transform the controlled signal to a transformed signal.
Step S908: Mix the delayed signal and the transformed signal, to generate a mixed signal.
Step S910: Remove a DC component of the mixed signal, to generate a removed signal.
Step S912: Compute the first path delay coefficient, the second path delay coefficient and a signal power according to the removed signal.
Step S914: Amplify an amplitude of the removed signal according to the signal power, to generate an amplified signal.
Step S916: Combine a plurality of chirps in the amplified signal, to generate a combined signal.
Step S918: End.

A detailed description and variations of the processes 80-90 can be known by referring to the above description, and are not narrated herein.

It should be noted that there are various possible realizations of the sensing device 10, the processing circuit 120 and the circuits in the sensing device 10 and the processing circuit 120. For example, the circuits mentioned above may be integrated into one or more circuits. In addition, the sensing device 10 and the processing circuit 120 may be realized by hardware (e.g. circuits), software, firmware (known as a combination of a hardware device, computer instructions and data that reside as read-only software on the hardware device), an electronic system or a combination of the devices mentioned above, but are not limited herein.

The operation of “determine” described above may be replaced by the operation of “compute”, “calculate”, “obtain”, “generate”, “output, “use”, “choose/select”, “decide” or “is configured to”. The phrase of “according to” described above may be replaced by “in response to”. The phrase of “corresponding to” described above may be replaced by “of” or “associated with”. The term of “via” described above may be replaced by “on”, “in” or “at”. The term “comprise” described above may be replaced by the term “is/are”. The terms “when” described above may be replaced by the term “in response to”.

To sum up, the present disclosure provides a circuit and a method for improving sensing accuracy. The gains described above (e.g., the gain for the removed signal, the combining gain and the transforming gain) are used for improving SNR in order to reduce the impact of noise and interference. In addition, an estimated path delay is obtained by computing path delay coefficients and signal power. A DC component is obtained when the estimated path delay approximates the actual path delay. The effect of leakage from the transmitter to the receiver is reduced by removing the DC component. Thus, the problem of how to improve the sensing accuracy can be solved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A processing circuit for improving a sensing accuracy, comprising:
a delay circuit, for outputting a delayed signal according to a first path delay coefficient;
a control circuit, for determining a clock phase sampling time according to a second path delay coefficient and outputting a controlled signal according to the clock phase sampling time;
a transforming circuit, coupled to the control circuit, for transforming the controlled signal to a transformed signal;
a mixing circuit, coupled to the delay circuit and the transforming circuit, for mixing the delayed signal and the transformed signal, to generate a mixed signal;
a removing circuit, coupled to the mixing circuit, for removing a direct current (DC) component of the mixed signal, to generate a removed signal;
a computing circuit, coupled to the delay circuit, the control circuit and the removing circuit, for computing the first path delay coefficient, the second path delay coefficient and a signal power according to the removed signal;
an amplifying circuit, coupled to the removing circuit and the computing circuit, for amplifying an amplitude of the removed signal according to the signal power, to generate an amplified signal; and
a combining circuit, coupled to the amplifying circuit, for combining a plurality of chirps in the amplified signal, to generate a combined signal.

2. The processing circuit of claim 1, wherein the step of the delay circuit outputting the delayed signal according to the first path delay coefficient comprises:
delaying an initial signal, to generate a plurality of candidate delayed signals; and
selecting a candidate delayed signal from the plurality of candidate delayed signals as the delayed signal according to the first path delay coefficient.

3. The processing circuit of claim 2, wherein the initial signal comprises a chirp.

4. The processing circuit of claim 1, wherein the step of the control circuit determining the clock phase sampling time according to the second path delay coefficient comprises:
dividing a sampling time of the transforming circuit into a plurality of candidate clock phase sampling times; and
selecting a candidate clock phase sampling time from the plurality of candidate clock phase sampling times as the clock phase sampling time according to the second path delay coefficient.

5. The processing circuit of claim 1, wherein the step of the computing circuit computing the first path delay coefficient, the second path delay coefficient and the signal power according to the removed signal comprises:
(A) setting a value of a phase counter as a first initial value, and setting the signal power as a second initial value;
(B) computing the first path delay coefficient and the second path delay coefficient according to the value, and triggering an output of an initial signal corresponding to the delayed signal;
(C) computing a power of the removed signal after a chirp time;
(D) increasing the value by 1, resetting that the signal power is equal to the power and performing the step (B) according to the increased value and the reset signal power, in response to the power being smaller than a sum of the signal power and a detection margin; and
(E) decreasing the value by 1 and computing the first path delay coefficient and the second path delay coefficient according to the decreased value, in response to the power not being smaller than the sum of the signal power and the detection margin.

6. The processing circuit of claim 5, wherein the computing circuit computes an estimated path delay according to at least one of the first path delay coefficient, the second path delay coefficient and the decreased value.

7. The processing circuit of claim 1, wherein the step of the amplifying circuit amplifying the amplitude of the removed signal according to the signal power to generate the amplified signal comprises:
computing a gain of the removed signal according to the signal power; and
multiplying the gain by the amplitude of the removed signal.

8. The processing circuit of claim 1, wherein the delay circuit comprises a delay line memory.

9. The processing circuit of claim 1, wherein the control circuit comprises a clock generator.

10. The processing circuit of claim 1, wherein the transforming circuit comprises an analog-to-digital converter (ADC).

11. The processing circuit of claim 1, wherein a combining gain is obtained by combining a plurality of chirps in the amplified signal through the combining circuit, in response to a neglect of a received phase change of a chirp in the amplified signal.

12. A method for improving a sensing accuracy, comprising:
outputting a delayed signal according to a first path delay coefficient;
determining a clock phase sampling time according to a second path delay coefficient and outputting a controlled signal according to the clock phase sampling time;
transforming the controlled signal to a transformed signal;
mixing the delayed signal and the transformed signal, to generate a mixed signal;
removing a direct current (DC) component of the mixed signal, to generate a removed signal;
computing the first path delay coefficient, the second path delay coefficient and a signal power according to the removed signal;
amplifying an amplitude of the removed signal according to the signal power, to generate an amplified signal; and
combining a plurality of chirps in the amplified signal, to generate a combined signal.

13. The method of claim 12, wherein the step of outputting the delayed signal according to the first path delay coefficient comprises:
delaying an initial signal, to generate a plurality of candidate delayed signals; and
selecting a candidate delayed signal from the plurality of candidate delayed signals as the delayed signal according to the first path delay coefficient.

14. The method of claim 13, wherein the initial signal comprises a chirp.

15. The method of claim 12, wherein the step of determining the clock phase sampling time according to the second path delay coefficient comprises:
dividing a sampling time into a plurality of candidate clock phase sampling times; and
selecting a candidate clock phase sampling time from the plurality of candidate clock phase sampling times as the clock phase sampling time according to the second path delay coefficient.

16. The method of claim 12, wherein the step of computing the first path delay coefficient, the second path delay coefficient and the signal power according to the removed signal comprises:
(A) setting a value of a phase counter as a first initial value, and setting the signal power as a second initial value;
(B) computing the first path delay coefficient and the second path delay coefficient according to the value, and triggering an output of an initial signal corresponding to the delayed signal;
(C) computing a power of the removed signal after a chirp time;
(D) increasing the value by 1, resetting that the signal power is equal to the power and performing the step (B) according to the increased value and the reset signal power, in response to the power being smaller than a sum of the signal power and a detection margin; and
(E) decreasing the value by 1 and computing the first path delay coefficient and the second path delay coefficient according to the decreased value, in response to the power not being smaller than the sum of the signal power and the detection margin.

17. The method of claim 16, wherein an estimated path delay is computed according to at least one of the first path delay coefficient, the second path delay coefficient and the decreased value.

18. The method of claim 12, wherein the step of amplifying the amplitude of the removed signal to generate the amplified signal comprises:
computing a gain of the removed signal according to the signal power; and
multiplying the gain by the amplitude of the removed signal.

19. The method of claim 12, wherein a combining gain is obtained by combining a plurality of chirps in the amplified signal, in response to a neglect of a received phase change of a chirp in the amplified signal.
